(19) United States
(12) Patent Application Publication
(10) Pub. No.: US 2016/0119995 A1
(43) Pub. Date: Apr. 28, 2016

(54) SIGNAL SMOOTHING DEVICE AND BACKLIGHT DEVICE INCLUDING THE SAME

(71) Applicant: Samsung Display Co., Ltd., Yongin-si (KR)

(72) Inventor: Songyi HAN, Asan-si (KR)

(21) Appl. No.: 14/789,286

(22) Filed: Jul. 1, 2015

(30) Foreign Application Priority Data
Oct. 24, 2014 (KR) 10-2014-0145328

(51) Int. Cl. H05B 33/08; H03K 17/18; H03K 5/1532; H03K 17/693

(52) U.S. Cl. CPC H05B 33/0851; H03K 17/693; H03K 17/18; H05B 33/0815; H05B 33/0824; H03K 5/1532

(57) ABSTRACT

A signal smoothing device includes: a plurality of capacitors connected in parallel between a conductive line and ground; a plurality of switches connected in series between the conductive line and each capacitor; and a switch selector configured to select one of the switches and to turn on the selected switch, based on a signal applied to the conductive line.

### CLAIM OF PRIORITY

This application claims priority to and all the benefits of Korean Patent Application No. 10-2014-0145328, filed on Oct. 24, 2014, with the Korean Intellectual Property Office (KIPO), the disclosure of which is incorporated herein in its entirety by reference.

### BACKGROUND OF THE INVENTION

1. Field of the Invention

Embodiments of the present invention relate to a signal smoothing device capable of extending life of a capacitor and a backlight device including the signal smoothing device.

2. Description of the Related Art

A signal smoothing device generally includes a capacitor. The capacitor may attenuate a ripple of signals applied to conductive lines to thereby smooth the signals.

Meanwhile, as driving time accumulates, smoothing capability of the capacitor may gradually deteriorate due to the life expectancy thereof. In particular, an electrolytic capacitor, which includes electrolyte thereinside, provides advantages of high capacity but has a substantially short life expectancy, compared to general capacitors, due to the electrolyte. In other words, an electrolytic capacitor may practically reach the end of its life, when electrolyte thereinside is exhausted.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY OF THE INVENTION

Aspects of embodiments of the present invention are directed to a signal smoothing device capable of extending life of a capacitor and a backlight device including the signal smoothing device.

According to an embodiment of the present invention, a signal smoothing device includes: a plurality of capacitors connected in parallel between a conductive line and ground; a plurality of switches connected in series between the conductive line and each capacitor; and a switch selector configured to select one of the switches and to turn on the selected switch, based on a signal applied to the conductive line.

The switch selector may select, instead of a switch currently having turn-on state, another switch and turns on the another selected switch, when the signal applied to the conductive line has a level out of a predetermined range.

The another switch may be one of the other switches except for switches currently having turn-on state or switches having turn-on history.

The switch selector may allow a switch currently having turn-on state to maintain its turn-on state, when the signal applied to the conductive line has a level in a predetermined range.

The switch selector may include: a peak detector configured to detect a peak value of a signal applied to the conductive line; a comparator configured to compare the peak value provided by the peak detector with a reference value, to produce a comparison signal having different levels based on the comparison result, and to transmit the comparison signal to the peak detector; and a selector configured to select one of the switches according to the comparison signal applied from the comparator and to output a selection signal to turn on the selected switch.

When the peak value is greater than the reference value, the comparator may output a comparison signal having a high logic value and the selector may apply the selection signal, instead of to a switch currently having turn-on state, to another switch in response to the comparison signal having a high logic value.

When the peak value is less than or equal to the reference value, the comparator may output a comparison signal having a low logic value and the selector may apply the selection signal to a switch currently having turn-on state in response to the comparison signal having a low logic value.

The plurality of capacitors may include an electrolytic capacitor.

According to another embodiment of the present invention, a signal smoothing device includes: a plurality of capacitors connected in parallel between a conductive line and ground; a plurality of switches connected in series between the conductive line and each capacitor; and a switch selector configured to count a time duration of an externally applied power signal, to select one of the switches based on the count result, and to turn on the selected switch.

The switch selector may select, instead of a switch currently having turn-on state, another switch, turn on the selected another switch, and count the time duration again from the beginning, when the time duration of the power signal is out of a predetermined range.

The another switch may be one of the other switches except for switches currently having turn-on state or switches having turn-on history.

The switch selector may allow a switch currently having turn-on state to maintain its turn-on state, when the time duration of the power signal is in a predetermined range.

According to an embodiment of the present invention, a backlight device includes: a light source array connected in series between a driving voltage transmission line and ground; a static-current switching element and a sensing resistor; a light source controller configured to control operation of the static-current switching element and to produce a feedback signal, based on a sensing voltage produced by the sensing resistor; a backlight driver configured to adjust a voltage level of a light source driving voltage applied to the driving voltage transmission line based on the feedback signal applied from the light source controller; a feedback transmission line connected between the light source controller and the backlight driver and configured to transmit the feedback signal; a plurality of capacitors connected in parallel between the feedback transmission line and ground; a plurality of switches connected in series between the feedback transmission line and each capacitor; and a switch selector configured to select one of the switches and to turn on the selected switch, based on the feedback signal applied to the feedback transmission line.

The switch selector may select, instead of a switch currently having turn-on state, another switch and turns on the selected another switch, when the feedback signal applied to the feedback transmission line has a level out of a predetermined range.

The another switch may be one of the other switches except for switches currently having turn-on state or switches having turn-on history.

The switch selector may allow a switch currently having turn-on state to maintain its turn-on state, when the feedback signal applied to the feedback transmission line has a level in a predetermined range.

According to another embodiment of the present invention, a backlight device includes: a light source array connected in series between a driving voltage transmission line and ground; a static-current switching element and a sensing resistor; a light source controller configured to control operation of the static-current switching element and to produce a feedback signal, based on a sensing voltage produced by the sensing resistor; a backlight driver configured to adjust a voltage level of a light source driving voltage applied to the driving voltage transmission line based on the feedback signal applied from the light source controller; a feedback transmission line connected between the light source controller and the backlight driver and configured to transmit the feedback signal; a plurality of capacitors connected in parallel between the feedback transmission line and ground; a plurality of switches connected in series between the feedback transmission line and each capacitor; and a switch selector configured to count a time duration of an externally applied power signal, to select one of the switches based on the count result, and to turn on the selected switch.

The switch selector may select, instead of a switch currently having turn-on state, another switch, turn on the selected another switch, and count the time duration again from the beginning, when the time duration of the power signal is out of a predetermined range.

The another switch may be one of the other switches except for switches currently having turn-on state or switches having turn-on history.

The switch selector may allow a switch currently having turn-on state to maintain its turn-on state, when the time duration of the power signal is in a predetermined range.

According to embodiments of the present invention, the signal smoothing device includes a plurality of capacitors capable of being selectively connected to a conductive line. Accordingly, when one of the capacitors has reached the end of its life and its smoothing capability deteriorates, another capacitor can be newly connected to the conductive line instead of the capacitor, thereby bringing about effect of extending life expectancy of the capacitor.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a view illustrating a signal smoothing device according to an exemplary embodiment;

FIGS. 2A to 2C are views illustrating operation of the signal smoothing device illustrated in FIG. 1;

FIG. 3 is a view illustrating a signal smoothing device according to another exemplary embodiment;

FIG. 4 is a view illustrating a signal smoothing device according to yet another exemplary embodiment;

FIG. 5 is a diagram illustrating a power signal and a clock signal applied to a switch selector illustrated in FIG. 4;

FIG. 6 is a block diagram illustrating a display device including the signal smoothing device according to an exemplary embodiment;

FIG. 7 is a detailed configuration view illustrating a display panel illustrated in FIG. 6;

FIG. 8 is a detailed configuration view illustrating a backlight device illustrated in FIG. 6

FIG. 9 is a view illustrating a backlight device including the signal smoothing device illustrated in FIG. 1 according to an exemplary embodiment; and

FIG. 10 is a view illustrating a backlight device including the signal smoothing device illustrated in FIG. 4 according to another exemplary embodiment.

### DETAILED DESCRIPTION OF THE INVENTION

Advantages and features of the present invention and methods for achieving them will be made clear from embodiments described below in detail with reference to the accompanying drawings. The present invention may, however, be embodied in many different forms and should not be construed as being limited to the embodiments set forth herein. Rather, these embodiments are provided so that this disclosure will be thorough and complete, and will fully convey the scope of the invention to those skilled in the art. The present invention is merely defined by the scope of the claims. Therefore, well-known constituent elements, operations and techniques are not described in detail in the embodiments in order to prevent the present invention from being obscurely interpreted. Like reference numerals refer to like elements throughout the specification.

In the drawings, thicknesses are illustrated in an enlarged manner in order to clearly describe a plurality of layers and areas. Like reference numbers are used to denote like elements throughout the specification. When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The spatially relative terms “below”, “beneath”, “lower”, “above”, “upper”, and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

Throughout the specification, when an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” can be termed likewise without departing from the teachings herein.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

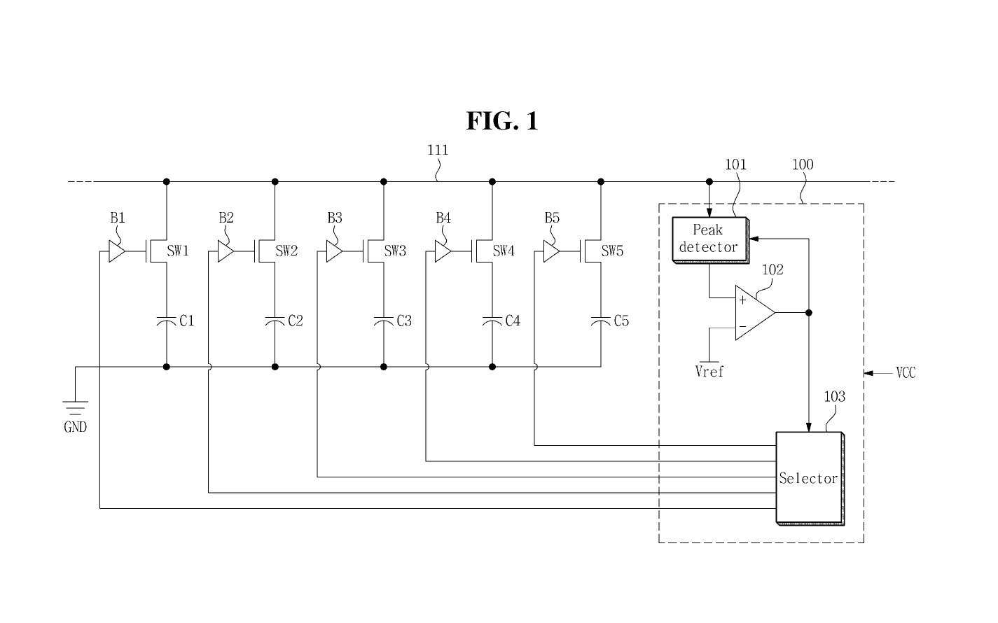

FIG. 1 is a view illustrating a signal smoothing device according to an exemplary embodiment.

The signal smoothing device according to an exemplary embodiment include, as illustrated in FIG. 1, a plurality of capacitors C1, C2, C3, C4, and C5, a plurality of switches SW1, SW2, SW3, SW4, and SW5, a plurality of buffers B1, B2, B3, B4, and B5, and a switch selector 100.

The capacitors C1, C2, C3, C4, and C5 are configured to attenuate a ripple of signals applied to a conductive line 111 to smooth the signal. One terminal of each capacitor C1, C2, C3, C4, and C5 is independently connected to each switch SW1, SW2, SW3, SW4, and SW5, and another terminal of each capacitor is connected to ground together. For instance, a k^{th} capacitor is connected between a k^{th} switch and ground. Herein, k is a natural number and may be one of numbers 1, 2, 3, 4, and 5, when the five capacitors C1, C2, C3, C4, and C5 and the five switches SW1, SW2, SW3, SW4, and SW5 are provided as illustrated in FIG. 1. At least one of the capacitors C1, C2, C3, C4, and C5 may be an electrolytic capacitor.

The switches SW1, SW2, SW3, SW4, and SW5 are configured to electrically connect the capacitors C1, C2, C3, C4, and C5 and the conductive line 111 or cut the connection therebetween. Each switch SW1, SW2, SW3, SW4, and SW5 is controlled by a selection signal applied from the switch selector 100 and connected between the conductive line 111 and a corresponding capacitor. For instance, the kth switch is controlled by a k^{th} selection signal and connected between the conductive line 111 and the k^{th} capacitor.

The capacitors C1, C2, C3, C4, and C5 are connected in parallel with each other. That is, the first to fifth capacitors C1, C2, C3, C4, and C5 are connected in parallel between the conductive line 111 and ground. Meanwhile, the k^{th} switch is connected between the conductive line 111 and the k^{th} capacitor in series.

The buffers B1, B2, B3, B4, and B5 are connected between the switch selector 100 and a gate electrode of each switch SW1, SW2, SW3, SW4, and SW5. Each buffer B1, B2, B3, B4, and B5 performs buffering of output applied from the switch selector 100 to provide it to each switch SW1, SW2, SW3, SW4, and SW5. Meanwhile, the buffers B1, B2, B3, B4, and B5 may be omitted.

The switch selector 100 is configured to select one of the switches based on a signal applied to the conductive line 111 to turn on the selected switch. With the operation of the switch selector 100, only one of the capacitors C1, C2, C3, C4, and C5 is electrically connected to the conductive line 111.

When the signal applied to the conductive line 111 has a level out of a predetermined range, the switch selector 100 selects, instead of a switch currently having turn-on state, another switch and turns on the another switch. Meanwhile, the other switches except for the turned-on another switch are all turned off or maintain their turn-off state. In this case, the another switch is a switch that is not ever turned on previously. In other words, the another switch is selected among the other switches except for switches currently having turn-on state or having turn-on history.

In contrast, when the signal applied to the conductive line 111 has a level within a predetermined range, the switch selector 100 allows the currently turned-on switch to maintain its turn-on state. Meanwhile, the other switches, except for the currently turned-on switch, are all turned off or maintain their turn-off state.

The switch selector 100 receives an externally applied power signal VCC to operate.

The switch selector 100 may include, as illustrated in FIG. 1, a peak detector 101, a comparator 102, and a selector 103.

The peak detector 101 is configured to detect a peak value of a signal applied to the conductive line 111. That is, the peak detector 101 detects a signal applied to the conductive line 111, detects a peak value of the detected signal, and outputs the detected peak value. In this case, the peak detector 101 looks for a peak value higher than a preceding peak value. Accordingly, the output provided from the peak detector 101 has a stepped voltage wavelength gradually increasing over time. Meanwhile, the peak detector 101 may be initialized according to a comparison signal applied from the comparator 102 described below.

The comparator 102 is configured to compare the peak value applied from the peak detector 101 to a predetermined reference value Vref and outputs a comparison signal of different levels according to the comparison result. For instance, when the peak value is greater than the reference value Vref, the comparator 102 may output a comparison signal having a high logic value. In contrast, when the peak value is less than or equal to the reference value Vref, the comparator 102 may output a comparison signal having a low logic value. Herein, the reference value Vref may be a direct current (DC) voltage having a constant value.

A peak value applied from the peak detector 101 is inputted to a non-inverting terminal (+) of the comparator 102 and the reference value Vref is inputted to an inverting terminal (−) of the comparator 102.

The selector 103 is configured to select one of the switches SW1, SW2, SW3, SW4, and SW5 according to the comparison signal applied from the comparator 102 to turn on the selected switch. When the comparison signal applied from the comparator 102 has a high logic value, the selector 103 selects, instead of a switch currently having turn-on state, another switch to turn on the selected switch. Meanwhile, the other switches, except for the another switch, are all turned off or maintain their turn-off state. Herein, as described above, the another switch is one of the other switches except for switches currently having turn-on state or having turn-on history.

The selector 103 may include a memory stored therein with state information of the switches SW1, SW2, SW3, SW4, and SW5. In other words, the state information is stored in the memory, which reports which switches currently have turn-on state, which switches have a turn-on history, and which switches do not have a turn-on history among the switches SW1, SW2, SW3, SW4, and SW5. The selector 103 selects a switch to turn on, based on the comparison signal applied from the comparator 102 and the state information of the switches stored in the memory. The state information is updated by the selector 103. For instance, in a case where a turned-on first switch SW1 is turned off, the selector 103 re-classifies the first switch SW1 from ‘a switch having turn-on state’ to ‘a switch having turn-on history’ and updates the state information to reflect the reclassification result.

The memory is a non-volatile memory that maintains the stored state information even after the power signal VCC is turned off. Accordingly, after the power signal VCC is turned off and on again, the switch that had turn-on state till the ‘off’ time point can be precisely selected again.

Meanwhile, the comparison signal applied from the comparator 102 is also inputted to the peak detector 101, as described above. In this case, only when the comparison signal has a high logic value, the peak detector 101 is initialized. The initialized peak detector 101 looks for a peak value higher than a predetermined initial value. Herein the initial value is voltage lower than the reference value Vref. Meanwhile, when the comparison signal has a low logic value, the peak detector 101 is not initialized. That is, when the comparison signal has a low logic value, the peak detector 101 looks for a peak value higher than a preceding peak value.

The operation of the signal smoothing device is described in detail with reference to drawings.

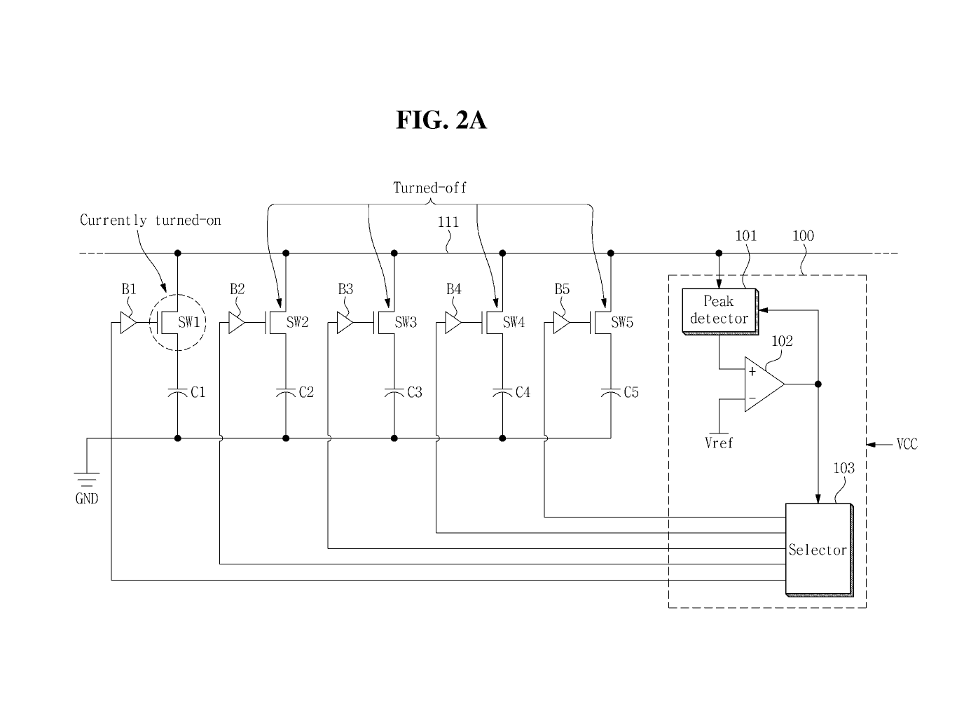

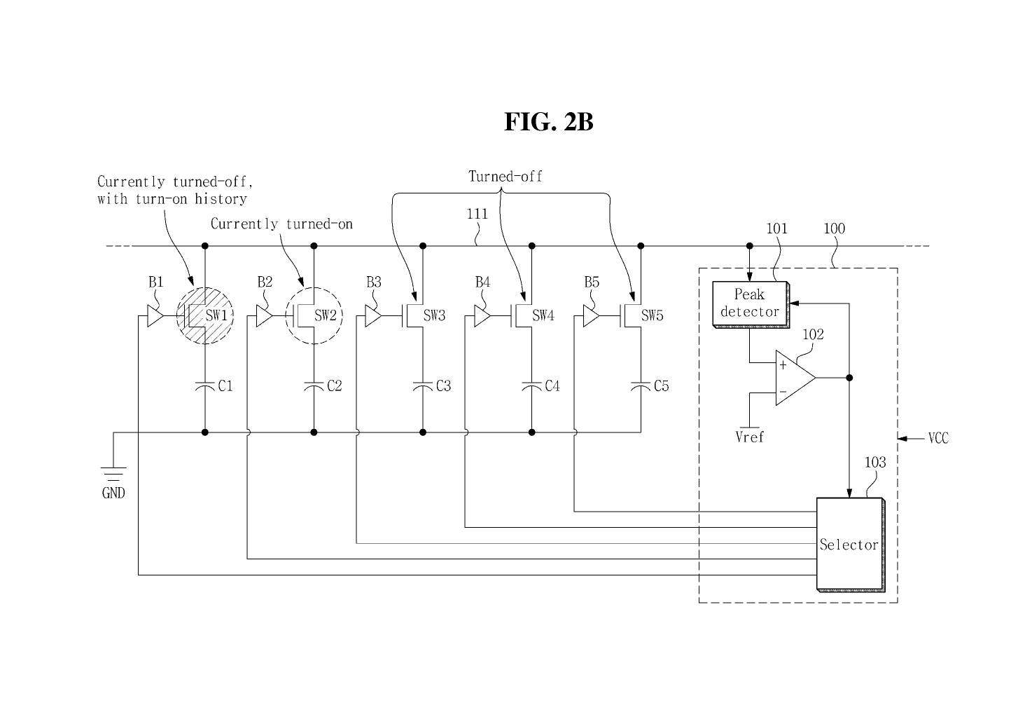

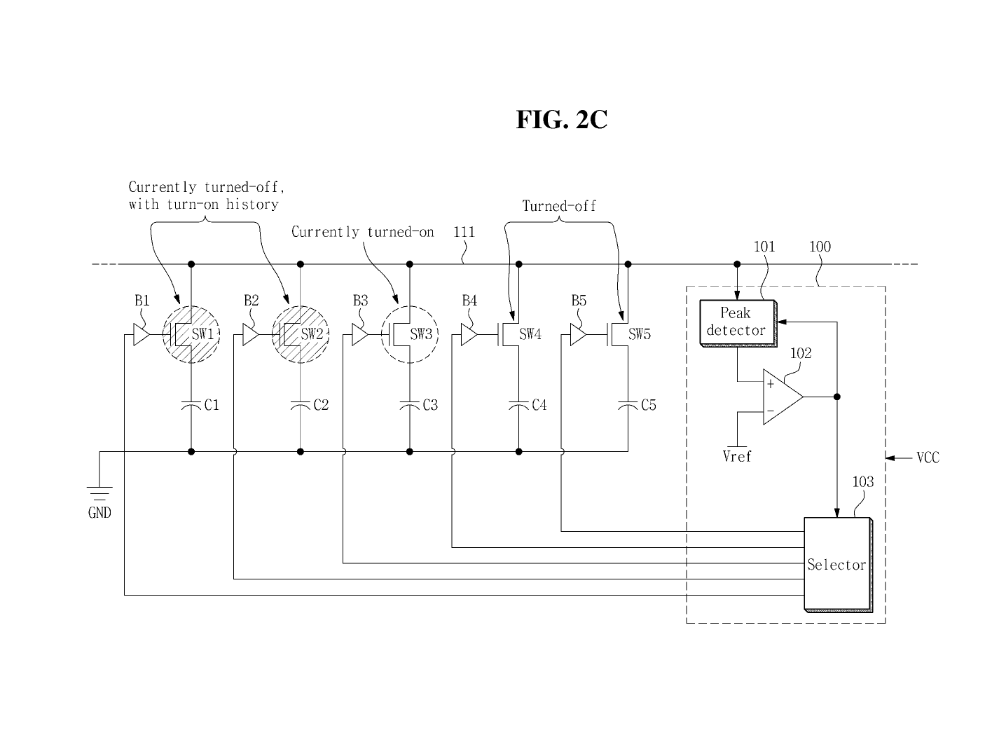

FIGS. 2A to 2C are views illustrating the operation of the signal smoothing device illustrated in FIG. 1. In FIGS. 2A to 2C, a switch surrounded by a dotted circle refers to a currently turned-on switch and a switch surrounded by a dotted circle with diagonal lines refers to a currently turned-off switch having turn-on history. Meanwhile, switches without any mark refer to currently turned-off switches not having turn-on history.

As illustrated in FIG. 2A when the switch SW1 is turned on, the first capacitor C1 is connected to the conductive line 111. In this case, the signal of the conductive line 111 is smoothed by the first capacitor C1. When the signal of the conductive line 111 has a peak value less than or equal to the reference value Vref, the comparator 102 outputs a comparison single having a low logic value according to a peak value applied through the peak detector 101. Then, in response to the comparison signal having a low logic value, the selector 103 allows the currently turned-on first switch SW1 to maintain its turn-on state and also allows the other second to fifth switches SW2, SW3, SW4, and SW5 to maintain their turn-off state. For this purpose, the selector 103 may provide a selection signal to the gate electrode of the first switch SW1 and may provide an off signal to each gate electrode of the respective second to fifth switches SW2, SW3, SW4, and SW5. The selection signal is a voltage set to be higher than a threshold voltage of the first to fifth switches SW1, SW2, SW3, SW4, and SW5 and the off signal is a voltage set to be lower than the threshold voltage of the first to fifth switches SW1, SW2, SW3, SW4, and SW5.

Meanwhile, as the driving time of the first capacitor C1 accumulates, the smoothing capability thereof may gradually deteriorate and a ripple level of the signal applied to the conductive line 111 may gradually increase. When the ripple level gradually increases to a point when the signal of the conductive line 111 has a peak value greater than the reference value Vref, the comparator 102 outputs a comparison signal having a high logic value according to the peak value applied through the peak detector 101. Then, as illustrated in FIG. 2B, in response to the comparison signal having a high logic value, the selector 103 turns on another switch, instead of the first switch SW1 currently having turn-on state. For instance, the selector 103 may turn on one of the second to fifth switches SW2, SW3, SW4, and SW5 not having turn-on history, that is, the second switch SW2. As the second switch SW2 is turned on, the second capacitor C2 is newly connected to the conductive line 111. Meanwhile, the selector 103 turns off the other switches SW1, SW3, SW4, and SW5, except for the another switch SW2. For this purpose, the selector 103 may provide a selection signal to the gate electrode of the second switch SW2 and may provide an off signal to each gate electrode of the respective first, third, fourth, and fifth switches SW1, SW3, SW4, and SW5. Further, the selector re-classifies the first switch SW1 to ‘a switch having turn-on history,’ re-classifies the second switch SW2 to ‘a switch having turn-on state,’ and re-classifies the third to fifth switches SW3, SW4, and SW5 to ‘a switch not having turn-on history.’ The re-classification result is reflected on the state information.

Meanwhile, the comparison signal having a high logic value outputted from the comparator 102 is inputted to the peak detector 101. Then, the peak detector 101 is initialized to have a peak value higher than the initial value.

Accordingly, when the first capacitor C1 reaches the end of its life and its smoothing capability deteriorates, the second capacitor C2 is newly connected to the conductive line 111 instead of the first capacitor C1. Accordingly, the ripple of the signal applied to the conductive line 111 is reduced again.

Meanwhile, as the driving time of the second capacitor C2 accumulates, the smoothing capability thereof may gradually deteriorate and a ripple level of the signal applied to the conductive line 111 may gradually increase. As the ripple level gradually increases to a point when the signal of the conductive line 111 has a peak value greater than the reference value Vref, the comparator 102 outputs a comparison signal having a high logic value according to the peak value applied through the peak detector 101. Then, as illustrated in FIG. 2C, in response to the comparison signal having a high logic value, the selector 103 turns on another switch, instead of the second switch SW2 currently having turn-on state. For instance, the selector 103 may turn on one of the third to fifth switches SW3, SW4, and SW5 not having turn-on history, that is, the third switch SW3. As the third switch SW3 is turned on, the third capacitor C3 is newly connected to the conductive line 111. Meanwhile, the selector 103 turns off the other switches SW1, SW2, SW4, and SW5, except for the another switch SW3. For this purpose, the selector 103 may provide a selection signal to the gate electrode of the third switch SW3 and may provide an off signal to each gate electrode of the respective first, second, fourth, and fifth switches SW1, SW2, SW4, and SW5. Further, the selector re-classifies the first and second switches SW1 and SW2 to ‘a switch having turn-on history,’ re-classifies the third switch SW3 to ‘a switch having turn-on state,’ and re-classifies the fourth and fifth switches SW4 and SW5 to ‘a switch not having turn-on history.’ The re-classification result is reflected on the state information.

Meanwhile, the comparison signal having a high logic value outputted from the comparator 102 is inputted to the peak detector 101. Then, the peak detector 101 is initialized to have peak value higher than the initial value.

Accordingly, the capacitor having reached the end of its life can be replaced by a new capacitor. The signal smoothing device according to an embodiment includes five capacitors C1, C2, C3, C4, and C5, but the number of capacitors is not limited thereto.

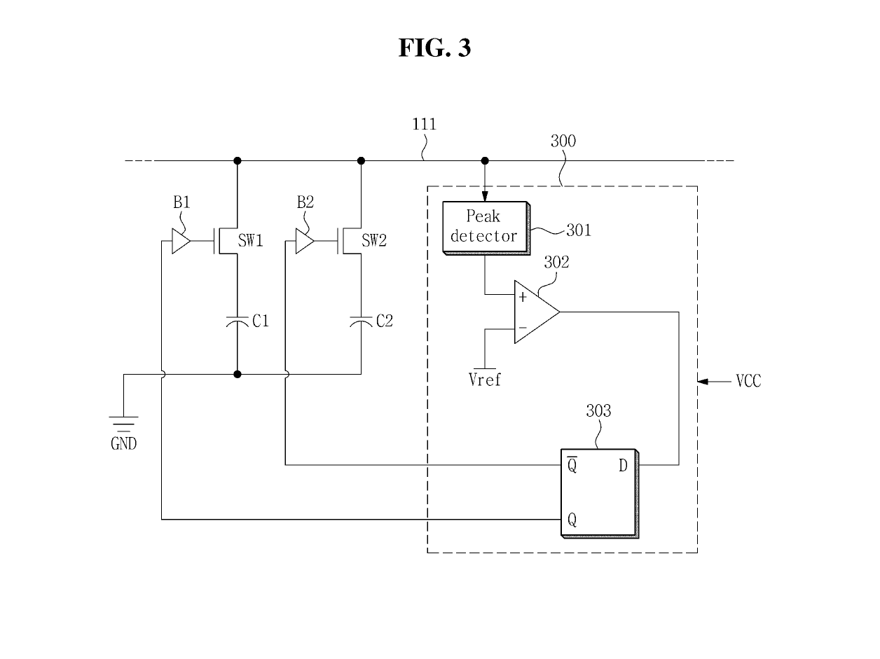

FIG. 3 is a view illustrating a signal smoothing device according to another exemplary embodiment.

The signal smoothing according to another embodiment includes, as illustrated in FIG. 3, first and second capacitors C1 and C2, first and second switches SW1 and SW2, first and second buffers B1 and B2, and a switch selector 300.

The first and second capacitors C1 and C2 are configured to attenuate a ripple of signals applied to the conductive line 111 to smooth the signal. Since the first and second capacitors C1 and C2 are substantially the same as the first and second capacitors C1 and C2 illustrated in FIG. 1, FIG. 1 and related description may be referred to. Meanwhile, at least one of the first and second capacitors C1 and C2 may be an electrolytic capacitor.

The first and second switches SW1 and SW2 are configured to electrically connect between the first and second capacitors C1 and C2 and the conductive line 111 or cut the connection therebetween. Since the first and second switches SW1 and SW2 are substantially the same as the first and second switches SW1 and SW2 illustrated in FIG. 1, FIG. 1 and related description may be referred to.

The first and second buffers B1 and B2 are connected between the switch selector 100 and a gate electrode of each switch SW1 and SW2. Since the first and second buffers B1 and B2 are substantially the same as the first and second buffers B1 and B2 illustrated in FIG. 1, FIG. 1 and related description may be referred to.

The switch selector 300 is configured to select one of the switches based on a signal applied to the conductive line 111 to turn on the selected switch. By operation of the switch selector 300, only one of the first and second capacitors C1 and C2 is electrically connected to the conductive line 111.

The switch selector 300 may include, as illustrated in FIG. 3, a peak detector 301, a comparator 302, and a selector 303.

The peak detector 301 is configured to detect a peak value of a signal applied to the conductive line 111. Since the peak detector 301 is substantially the same as the peak detector 101 illustrated in FIG. 1, FIG. 1 and related description may be referred to. However, the peak detector 301 illustrated in FIG. 3 is not supplied with a comparison signal from the comparator 302.

The comparator 302 is configured to compare the peak value applied from the peak detector 301 with a predetermined reference value Vref and output a comparison signal having different levels according to the comparison result. Since the comparator 302 is substantially the same as the comparator 102 illustrated in FIG. 1, FIG. 1 and related description may be referred to. However, the comparator 302 illustrated in FIG. 3 does not apply a comparison signal to the peak detector 301.

The selector 303 is configured to select one of the switches according to the comparison signal applied from the comparator 302 to turn on the selected switch. When the comparison signal applied from the comparator 302 has a high logic value, the selector 303 selects, instead of a switch currently having turn-on state, another switch and turns on the selected switch. For instance, when the first switch SW1 is a currently turned-on switch, the selector 303 may turn off the first switch SW1 and turn off the second switch SW2.

The selector 303 may be a flip-flop. In this case, the selector 303 may invert output logic outputted through a terminal Q and a terminal Q-bar, according to comparison signal logic applied to an input terminal D. For instance, when the comparison signal inputted to the input terminal D has a low logic value, output of the terminal Q may have a high logic value, while output of the terminal Q-bar may have a low logic value. In some embodiments, when the comparison signal inputted to the input terminal D has a high logic value, the output of the terminal Q may have a low logic value, while the output of the terminal Q-bar may have a high logic value.

Operation of the signal smoothing device is described below in more detail.

First, when the first switch SW1 is turned on, the first capacitor C1 is connected to the conductive line 111. In this case, the signal of the conductive line 111 is smoothed by the first capacitor C1. When the signal of the conductive line 111 has a peak value less than or equal to the reference value Vref, the comparator 302 outputs a comparison signal having a low logic value according to a peak value applied through the peak detector 301. Then, in response to the comparison signal having a low logic value, the selector 303 allows the currently turned-on first switch SW1 to maintain its turn-on state and also allows the currently turn-off second switch SW2 to maintain its turn-off state. For this purpose, the selector 303 may provide a selection signal to a gate electrode of the first switch SW1 through the terminal Q and may provide an off signal to a gate electrode of the second switch SW2 through the terminal Q-bar. The selection signal is a voltage set to be higher than a threshold voltage of the first and second switches SW1 and SW2, and the off signal is a voltage set to be lower than the threshold voltage of the first and second switches SW1 and SW2.

Meanwhile, as the driving time of the first capacitor C1 accumulates, the smoothing capability thereof may gradually deteriorate and a ripple level of the signal applied to the conductive line 111 may gradually increase. When the ripple level gradually increases to a point when the signal of the conductive line 111 has a peak value greater than the reference value Vref, the comparator 302 outputs a comparison signal having a high logic value according to the peak value applied through the peak detector 301. Then, in response to the comparison signal having a high logic value, the selector 303 turns off the first switch SW1 currently having turn-on state and turns on the second switch SW2. For this purpose, the selector 303 may provide a selection signal to the gate electrode of the second switch SW2 through the terminal Q-bar and may provide an off signal to the gate electrode of the first switches SW1 through the terminal Q.

As the second switch SW2 is turned on, the second capacitor C2 is newly connected to the conductive line 111.

Meanwhile, even after the comparison signal having a high logic value is outputted, the peak detector 301 is not initialized, and thus a peak value that is provided by the peak detector 301 after the comparison signal having a high logic value is outputted is always greater than the reference value Vref. Accordingly, after the comparison signal having a high logic value is outputted, the comparison signal outputted from the comparator 302 always has a high logic value. Accordingly, when the second switch SW2 is once turned on, the first switch SW1 cannot be turned on any longer.

Accordingly, as the first capacitor C1 has reached the end of its life and the smoothing capability thereof deteriorates, the second capacitor C2 is newly connected to the conductive line 111, instead of the first capacitor C1. Accordingly, the ripple level of the signal applied to the conductive line 111 starts to reduce again.

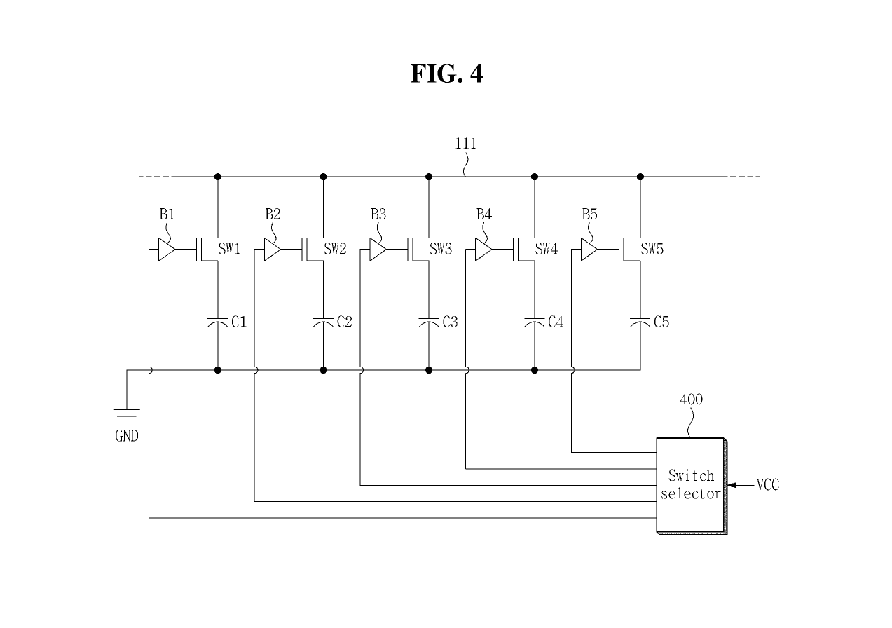

FIG. 4 is a view illustrating a signal smoothing device according to yet another exemplary embodiment.

The signal smoothing device according to yet another exemplary embodiment includes, as illustrated in FIG. 4, a plurality of capacitors C1, C2, C3, C4, and C5, a plurality of switches SW1, SW2, SW3, SW4, and SW5, a plurality of buffers B1, B2, B3, B4, and B5, and a switch selector 400.

The capacitors C1, C2, C3, C4, and C5 are configured to attenuate a ripple of signals applied to the conductive line 111 to smooth the signal. Since the capacitors C1, C2, C3, C4, and C5 are substantially the same as the capacitors C1, C2, C3, C4, and C5 illustrated in FIG. 1, FIG. 1 and related description may be referred to. Meanwhile, at least one of the capacitors C1, C2, C3, C4, and C5 illustrated in FIG. 4 may be an electrolytic capacitor.

The switches SW1, SW2, SW3, SW4, and SW5 are configured to electrically connect the capacitors C1, C2, C3, C4, and C5 and the conductive line 111 or cut the connection therebetween. Since the switches SW1, SW2, SW3, SW4, and SW5 illustrated in FIG. 4 are substantially the same as the switches SW1, SW2, SW3, SW4, and SW5 illustrated in FIG. 1, FIG. 1 and related description may be referred to.

The buffers B1, B2, B3, B4, and B5 are connected between the switch selector 400 and a gate electrode of each switch SW1, SW2, SW3, SW4, and SW5. Since the buffers B1, B2, B3, B4, and B5 illustrated in FIG. 4 are substantially the same as the first and second buffers B1 and B2 illustrated in FIG. 1, FIG. 1 and related description may be referred to.

The switch selector 400 is configured to count a time duration during which an externally applied power signal VCC maintains on-state (hereinafter, time duration of the power signal VCC) and to select one of the switches based on the count result to turn on. Herein, the time duration refers to an accumulated time during which the power signal VCC maintains the on-state. For instance, when the power signal VCC having on-state changes its state to off-state and then changes again to on-state to maintain it, the time duration refers to the total time length of first and second on-state periods.

The switch selector 400 may include first and second memories thereinside. The first memory is substantially the same as the above-described memory. That is, the state information of the switches is stored in the first memory. Time duration is stored in the second memory. The first and second memories are non-volatile memories, which maintain stored information after the power signal VCC is turned off. Accordingly, even after the power signal VCC is turned off, information of a switch which was turned on till the off-time point and of total accumulated time till the off-time point can be preserved.

When the time duration of the power signal VCC is out of a predetermined range, the switch selector 400 selects, instead of a switch currently having turn-on state, another switch and turns on the selected switch. Meanwhile, the other switches except for the turn-on another switch are all turned off or maintain their turn-off state. In this case, the another switch is a switch that has not been turned on previously. In other words, the another switch is selected among the other switches except for switches currently having turn-on state or having turn-on history. Further, the switch selector 400 turns on the another switch and starts to count the time duration again from the beginning. Accordingly, the time duration of the new capacitor selected by the newly turned-on switch can be accurately measured.

In contrast, when the time duration of the power signal VCC is in a predetermined range, the switch selector 400 allows the turned-on switch to maintain its turn-on state. Meanwhile, the other switches except for the switch currently having turn-on state are all turned off or maintain their turn-off state.

For instance, when the time duration of the power signal VCC is longer than a predetermined critical value, the switch selector 400 turns on, instead of a switch currently having turn-on state, another switch. In contrast, when the time duration of the power signal VCC is less than or equal to the predetermined critical value, the switch selector 400 may allow the switch currently having turn-on state to maintain its turn-on state.

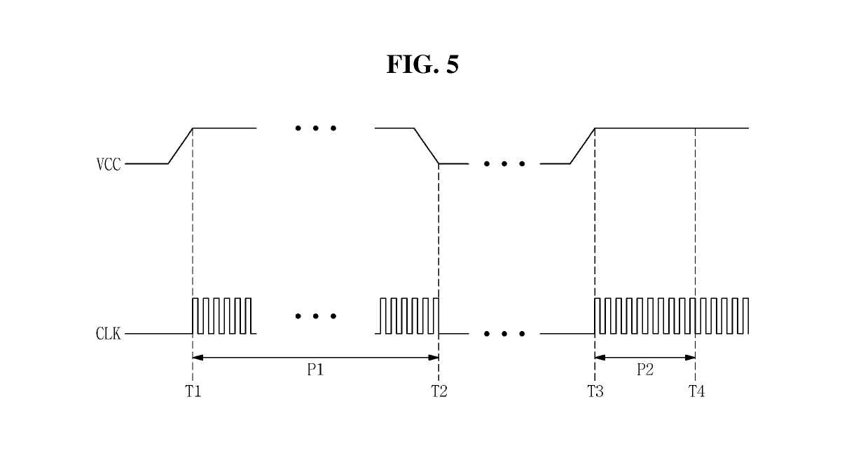

FIG. 5 is a diagram illustrating a power signal VCC and a clock signal applied to a switch selector illustrated in FIG. 4.

As illustrated in FIG. 5, from a first on-time point T1 when the power signal VCC is firstly turned on, the switch selector 400 starts to count impulses included in the clock signal CLK. Then, at an off-time point T2 of the power signal VCC, the switch selector 400 stops counting. Herein, it is assumed that the number of counted impulses is less than a critical value during a period P1 from the first on-time point T1 to the off-time point T2. Then, the switch selector 400 stores the number of impulses counted from the first on-time point T1 to the off-time point T2 in the second memory. Further, the switch selector 400 stores the state information of each switch in the first memory. For instance, when the first switch SW1 is turned on, and the other switches SW2, SW3, SW4, and SW5 are all turned off, the switch selector 400 classifies the first switch SW1 to ‘a switch having turn-on state,’ classifies the other switches SW2, SW3, SW4, and SW5 to ‘a switch not having turn-on history’ and updates the state information to reflect the classification result.

Then, when the power signal VCC is turned on again after a predetermined time, the switch selector 100 starts to count impulses again from a second on-time point T3. In this case, the number of impulses is counted with respect to a number stored in the second memory. For instance, when a number 100 is stored in the second memory, the first impulse occurring at the second on-time point T3 is imparted with a number 101. In other words, the switch selector 400 starts to count from 101 at the second on-time point T3.

If the critical value is assumed be 110, at a time point when total counted time is 110, the switch selector 400 turns on, instead of the first switch SW1 currently having turn-on state, another switch. That is, when the total number of counted impulses during the first period P1 and counted impulses during the second period P2 is 110, the switch selector 400 turns on, instead of the first switch SW1 currently having turn-on state, another switch. For instance, the switch selector 400 may turn on one of the second, third, fourth, and fifth switches SW2, SW3, SW4, and SW5 not having turn-on history, that is, the second switch SW2. As the second switch SW2 is turned on, the second capacitor C3 is newly connected to the conductive line 111. Meanwhile, the switch selector 400 turns off the other switches SW1, SW3, SW4, and SW5, except for the another switch SW2. For this purpose, the switch selector 400 may provide a selection signal to the gate electrode of the second switch SW2 and may provide an off signal to each gate electrode of the respective first, third, fourth, and fifth switches SW1, SW3, SW4, and SW5.

Further, the switch selector 400 re-classifies the first switch SW1 to ‘a switch having turn-on history,’ re-classifies the second switch SW2 to ‘a switch having turn-on state,’ and re-classifies the third, fourth, and fifth switches SW3, SW4 and SW5 to ‘a switch not having turn-on history.’ The re-classification result is reflected on the state information stored in the first memory. Further, at a time point T4 when total counted time is 110, the switch selector 400 initializes the time duration stored in the second memory to 0. Then, when the power signal VCC is an on-voltage, the switch selector 400 starts to count the time duration again from the beginning, that is, from 1.

According to the above-described manner, the capacitor that has reached the end of its life can be replaced by a new capacitor. The signal smoothing device according to an exemplary embodiment includes five capacitors, but the number of the capacitors is not limited thereto.

Meanwhile, the signal smoothing device according to an exemplary embodiment may be applied to a backlight device of a display device, which is described below in more detail with reference to the drawings.

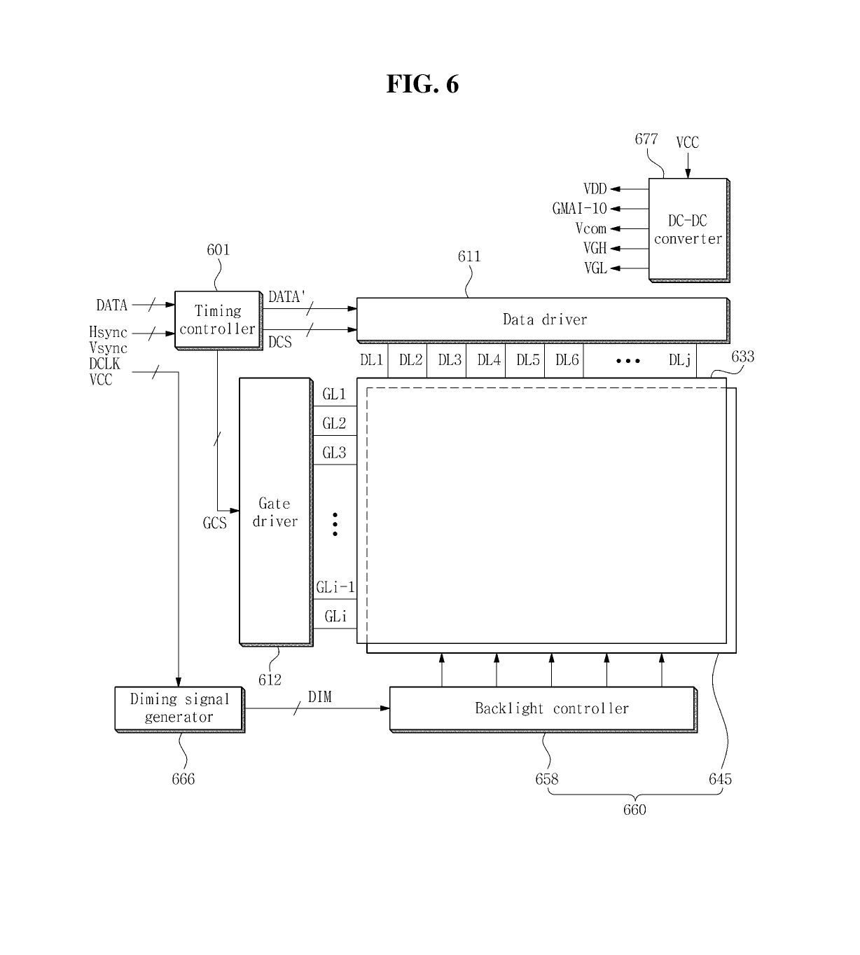

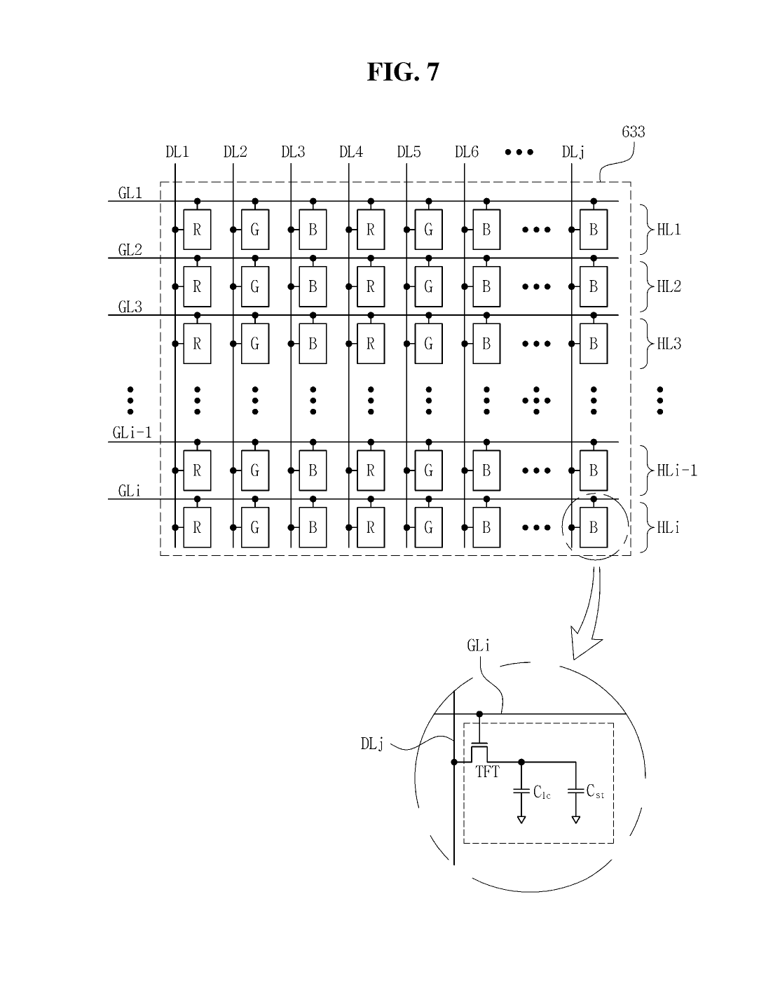

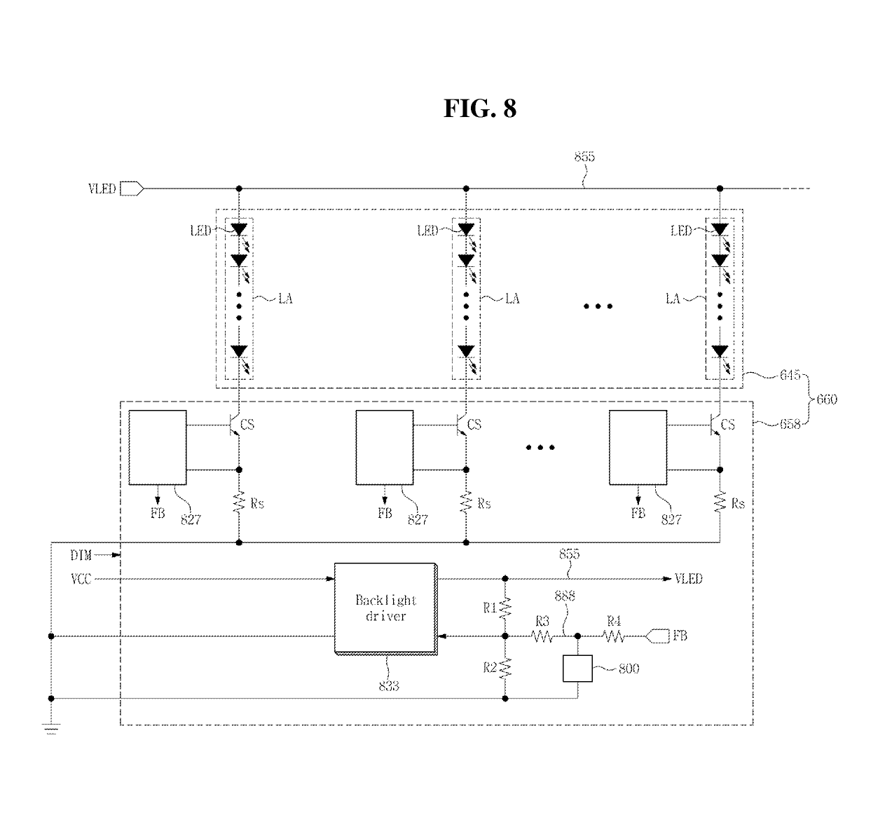

FIG. 6 is block diagram illustrating a display device including the signal smoothing device according to an exemplary embodiment. FIG. 7 is a detailed configuration view illustrating a display panel illustrated in FIG. 6. FIG. 8 is a detailed configuration view illustrating a backlight device illustrated in FIG. 6.

A display device includes, as illustrated in FIG. 6, a display panel 633, a backlight unit 645, a backlight controller 658, a dimming signal generator 666, a timing controller 601, a gate driver 612, a data driver 611, and a DC-DC converter 677. Herein, the backlight device 660 includes the backlight unit 645 and the backlight controller 658.

The display panel 633 is configured to display an image. The display panel 633 includes, although not illustrated, a liquid crystal layer and lower and upper substrates opposed to each other with the liquid crystal layer interposed therebetween.

On the lower substrate, a plurality of gate lines GL1 to GLi, a plurality of data lines DL1 to DLj intersecting the gate lines GL1 to GLi, and thin film transistors (“TFTs”) connected to the gate lines GL1 to GLi and the data lines DL1 to DLj are disposed.

Although not illustrated, a black matrix, a plurality of color filters, and a common electrode are disposed on the upper substrate. The black matrix is disposed on the upper substrate, except for an area corresponding to a pixel region. The color filters are disposed on the pixel region. The color filters are categorized into red, green, and blue color filters.

Pixels R, G, and B are arranged in a matrix form. The pixels R, G, and B are categorized into red pixels R disposed corresponding to the red color filter, green pixels G disposed corresponding to the green color filter, and blue pixels B disposed corresponding to the blue color filter. In this case, the red, green, and blue pixels R, G, and B adjacently disposed in a horizontal direction form a unit pixel to display a unit image.

There are j pixels arranged along an n^{th} (n is a number selected from 1 to i) horizontal line (hereinafter, n^{th} horizontal line pixels) and respectively connected to the first to the j^{th} data lines DL1 to DLj. Further, the n^{th} horizontal line pixels are connected to the n^{th} gate line together. Accordingly, the n^{th} horizontal line pixels receive an n^{th} gate signal together. That is, j pixels aligned in the same horizontal line receive the same gate signal, while pixels arranged in different horizontal lines receive different gate signals. For example, both red and green pixels R and G disposed on the first horizontal line HL1 receive a first gate signal, while red and green pixels R and G disposed on the second horizontal line HL2 receive a second gate signal that has a different timing compared to the first gate signal.

Each of the pixels R, G, B includes, as illustrated in FIG. 2, a TFT, a liquid crystal storage capacitor Clc, and an auxiliary storage capacitor Cst.

The TFT is turned on according to a gate signal applied from the gate line. The turned-on TFT supplies an analog image data signal applied from the data line to the liquid crystal capacitor Clc and the auxiliary storage capacitor Cst.

The liquid crystal storage capacitor Clc includes a pixel electrode and a common electrode opposed to each other.

The auxiliary storage capacitor Cst includes a pixel electrode and an opposing electrode opposed to each other. Herein, the opposing electrode may be a previous gate line or a common line that may transmit a common voltage.

Meanwhile, among elements forming the pixels R, G, and B, the TFT is covered by the black matrix.

The timing controller 601 is configured to receive a vertical synchronization signal Vsync, a horizontal synchronization signal Hsync, an image data signal DATA, and a clock signal DCLK outputted from a graphic controller provided in a system. An interface circuit (not illustrated) is provided between the timing controller 601 and the system, and the signals outputted from the system are inputted to the timing controller 601 through the interface circuit. The interface circuit may be equipped in the timing controller 601.

Although not illustrated, the interface circuit includes a low voltage differential signaling LVDS receiver. The interface circuit lowers voltage levels of the vertical synchronization signal Vsync, the horizontal synchronization signal Hsync, the image data signal DATA, and the clock signal DCLK outputted from the system, but also increases frequencies of the signals.

Meanwhile, due to a high-frequency component of the signal inputted from the interface circuit to the timing controller 601, electromagnetic interference may be caused therebetween. In order to prevent the interference, an EMI filter (not illustrated) may be further provided between the interface circuit and the timing controller 601.

The timing controller 601 generates a gate control signal to control the gate driver 612 and a data control signal to control the data driver 611, using the vertical synchronization signal Vsync, the horizontal synchronization signal Hsync, and the clock signal DCLK. The gate control signal includes a gate start pulse, a gate shift clock, a gate output enable signal, and the like. The data control signal includes a source start pulse, a source shift clock, a source output enable signal, a polarity signal, and the like.

Further, the timing controller 601 rearranges the image data signals DATA inputted from the system and supplies the rearranged image data signals DATA′ to the data driver 611.

Meanwhile, the timing controller 601 is operated by a driving power Vcc outputted from a power unit provided in the system. In particular, the driving power Vcc is used as a power voltage of a phase lock loop PLL equipped in the timing controller 601. The phase lock loop PLL compares the clock signal DCLK inputted to the timing controller 601 with a reference frequency generated from an oscillator. In a case where there is a difference between the compared values, the phase lock loop PLL adjusts the frequency of the clock signal by the difference, so as to produce a sampling clock signal. The sampling clock signal is a signal to perform sampling of the image data signals DATA′.

The DC-DC converter 677 increases or decreases the driving power signal VCC inputted through the system to thereby produce voltages required for the display panel 633. For this purpose, the DC-DC converter 677 may include, for example, an output switching element for switching an output voltage of an output terminal thereof; and a pulse width modulator PWM for controlling a duty ratio or a frequency of a control signal applied to a control terminal of the output switching element so as to increase or decrease the output voltage. Herein, the DC-DC converter 677 may include a pulse frequency modulator PFM, instead of the pulse width modulator PWM.

The pulse width modulator PWM increases the duty ratio of the above-described control signal to thereby increase the output voltage of the DC-DC converter 677 or decreases the duty ratio of the control signal to thereby lower the output voltage of the DC-DC converter 677. The pulse frequency modulator PFM increases the frequency of the above-described control signal to thereby increase the output voltage of the DC-DC converter 677 or decreases the frequency of the control signal to thereby lower the output voltage of the DC-DC converter 677. The output voltage of the DC-DC converter 677 includes a reference voltage VDD of about 6[V] or more, a gamma reference voltage GMA1-10 of lower than level 10, a common voltage in a range from about 2.5 to 3.3[V], a gate high voltage of about 15[V] or more, and a gate low voltage of −4[V] or less.

The gamma reference voltage GMA1-10 is voltage generated by voltage division of the reference voltage. The reference voltage and the gamma reference voltage are analog gamma voltages, and provided to a data driving integrated circuit D-IC. The common voltage is applied to a common electrode of the display panel 633 via the data driving integrated circuit D-IC. The gate high voltage is a high logic voltage of the gate signal, which is set to be a threshold voltage or higher of the TFT. The gate low voltage is a low logic voltage of the gate signal, which is set to be an off-voltage of the TFT. The gate high voltage and the gate low voltage are applied to the gate driver 612.

The gate driver 612 is configured to produce gate signals according to the gate control signal (GCS) applied from the timing controller 601 and sequentially apply the gate signals to the plurality of gate lines GL1 to GLi. The gate driver 612 may include, for example, a shift register configured to shift the gate start pulse to produce the gate signals, according to the gate shift clock. The shift register may include a plurality of switching elements. The switching elements may be formed on a front surface of the lower substrate in the same process as in the TFT of the display area.

The data driver 611 is configured to receive the image data signals (DATA′) and the data control signal DCS from the timing controller 601. The data driver 611 performs sampling of the image data signals (DATA′) according to the data control signal DCS, performs latching of the sampled image data signals corresponding to one horizontal line each horizontal period, and applies the latched image data signals to the data lines DL1 to DLj. In other words, the data driver 611 converts the image data signals DATA′ applied from the timing controller 601 into analog image data signals using the gamma reference voltages GMA1-10 inputted from the DC-DC converter 677 and provides them to the data lines DL1 to DLj.

The backlight unit 645 is configured to provide light to the display panel 633. The backlight unit 645 includes, as illustrated in FIG. 8, a plurality of light source arrays LAs.

Each of the light source array LA1 to LAk includes a plurality of light emitting diodes (“LEDs”). The LEDs provided in one light source array are connected to each other in series.

Each of the light source array LA1 to LAk receives a light source driving voltage VLED together through a driving voltage transmission line. The light source driving voltage VLED is applied to an anode electrode of the LED disposed at an upper outermost portion in each of the light source array LA1 to LAk.

The light source driving voltage VLED may be applied from a backlight driver. The backlight driver is configured to increase or decrease a power signal VCC applied from the system to generate various signals required for operation of the backlight unit 645. The light source driving voltage VLED is one of the signals. The backlight driver may be equipped in the backlight controller 658.

The LED may be a light emission package including at least one LED. In some embodiments, the light emission package may include a red LED that emits red light, a green LED that emits green light, and a blue LED that emits blue light therein. The light emission package may combine light of three colors to produce white light. In some embodiments, the light package may include only a blue LED therein among the above-described LEDs of three colors. In this case, fluorescent members (e.g., phosphors) may be formed in a light emitting unit of the blue LED so as to convert blue light into white light.

The backlight unit 645 may be one of a direct-lit backlight, an edge-lit backlight, and a corner-lit backlight. An exemplary direct-lit backlight unit 645 is illustrated in FIG. 8.

The dimming signal generator 666 is configured to receive a vertical synchronization signal Vsync, a horizontal synchronization signal Hsync, an image data signal DATA, and a clock signal DCLK outputted from a system. In this case, the dimming signal generator 666 receives the signals through the interface circuit.

The dimming signal generator 666 is configured to separate image data signals of one frame into a luminance component and a chrominance component, to analyze the luminance component to calculate an average luminance corresponding to one frame image, and to thereby produce a dimming signal based on the calculated average luminance. For instance, in a case where image data of one frame has a bright image having a high average luminance, a dimming signal having a high value is generated to increase luminance of the backlight unit 645. In contrast, in a case where the image data of one frame has a dark image having a low average luminance, a dimming signal having a low value is generated to decrease luminance of the backlight unit 645.

Meanwhile, the backlight unit 645 may be controlled in a global dimming method or a local dimming method.

According to the global dimming method, the entire light source arrays LA1 to Lak are controlled by one dimming signal. In this case, the dimming signal generator 666 may produce one dimming signal.

In contrast, according to the local dimming method, the respective light source arrays LA1 to Lak are independently controlled by each corresponding dimming signal. In this case, the dimming signal generator 666 may produce dimming signals of the number of the light source arrays. In this case, each dimming signal may have the same value or may have different values according to characteristics of an image of one frame. In some embodiments, the light source arrays disposed corresponding to a bright portion of an image of one frame may be controlled by a dimming signal having a high value and the light source arrays disposed corresponding to a dark portion of the image of one frame may be controlled by a dimming signal having a low value.

The backlight controller 658 controls luminance of the backlight unit 645 according to one dimming signal or a plurality of dimming signals applied from the dimming signal generator 666.

The backlight controller 658 includes a plurality of light source controllers 827, a plurality static current switching elements CS, a plurality of sensing resistors Rs, and a backlight driver 833. Each light source controller 827 controls luminance of each light source arrays LA according to the dimming signal DIM.

A light source array LA and the static current switching element CS and the sensing resistor Rs that are connected to the light source array LA are connected to each other in series between the driving voltage transmission line 855 and ground.

The light source controllers 827 controls operation of the static current switching element CS based on the sensing voltage generated by the sensing resistor Rs and also produces a feedback signal FB.

The backlight driver 833 adjusts a voltage level of the light source driving voltage VLED applied to the driving voltage transmission line 855 based on the feedback signal FB applied from the light source controller 827. The backlight driver 833 is configured to increase or decrease an externally applied power signal VCC according to the feedback signal FB applied thereto, thereby controlling a voltage level of the light source driving voltage VLED. A plurality of resistors R1, R2, R3, and R4 and a signal smoothing device 801 are connected to each other in parallel between input and output terminals of the backlight driver 833.

The feedback transmission line 888 is connected between the light source controller 827 and the backlight driver 833 to transmit the feedback signal FB.

The static current switching element CS may include a bipolar transistor including a base terminal, a collector terminal, and an emitter terminal. The base terminal of the static current switching element CS is connected to the light source controller 827, the collector terminal is connected to the light source array LA, and the emitter terminal is connected to ground through the sensing resistor Rs.

The signal smoothing device 801 provided in the backlight device 660 may have configurations of the signal smoothing devices 100, 300, and 400 illustrated in FIGS. 1, 3, and 4, which is described below in more detail with reference to the drawings.

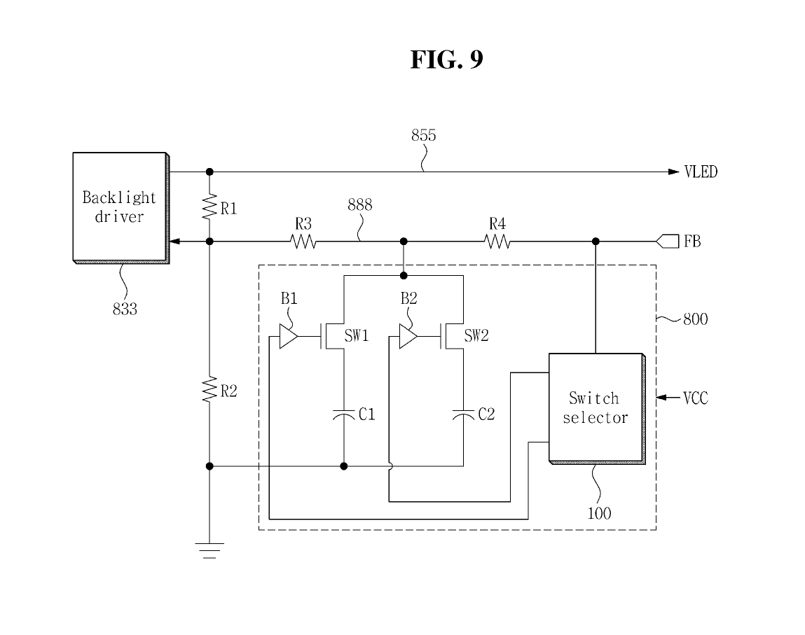

FIG. 9 is a view illustrating a backlight device 660 including the signal smoothing device illustrated in FIG. 1 according to an exemplary embodiment.

The backlight device 660 according to an exemplary embodiment includes, as illustrated in FIG. 9, a plurality of capacitors C1 and C2, a plurality of switches SW1 and SW2, a plurality of buffers B1 and B2, and a switch selector 100.

The capacitors C1 and C2 are configured to attenuate a ripple of a feedback signal FB applied to a feedback transmission line 888 to thereby smooth the feedback signal FB. Since the capacitors C1 and C2 illustrated in FIG. 9 are substantially the same as the first and second capacitors C1 and C2 illustrated in FIG. 1, FIG. 1 and related description may be referred to.

The switches SW1 and SW2 are configured to electrically connect the capacitors C1 and C2 and the feedback transmission line 888 or cut the connection therebetween. Since the switches SW1 and SW2 illustrated in FIG. 9 are substantially the same as the first and second of switches SW1 and SW2 illustrated in FIG. 1, FIG. 1 and related description may be referred to.

The buffers B1 and B2 are connected between the switch selector 100 and a gate electrode of each of the switches. Since the buffers B1 and B2 are substantially the same as the first and second buffers B1 and B2 illustrated in FIG. 1, FIG. 1 and related description may be referred to.

The switch selector 100 is configured to select one of the switches based on the feedback signal FB applied to the feedback transmission line 888 and to turn on the selected switch. By operation of the switch selector 100, only one of the capacitors C1 and C2 is electrically connected to the feedback transmission line 888. Since the switch selector 100 is substantially the same as the switch selector 100 illustrated in FIG. 1, FIG. 1 and related description may be referred to.

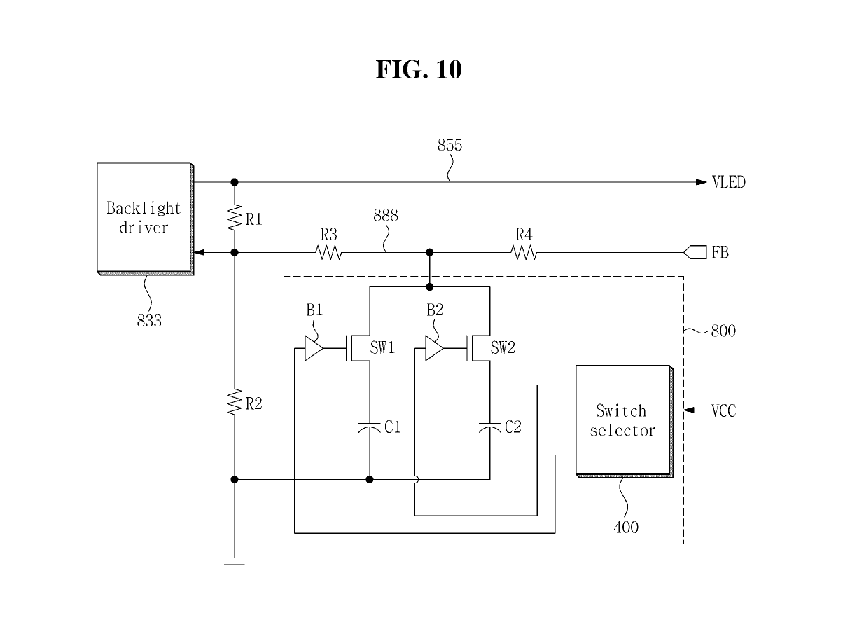

FIG. 10 is a schematic configuration view illustrating a backlight device including the signal smoothing device illustrated in FIG. 4 according to another exemplary embodiment.

The backlight device 660 according to another exemplary embodiment includes, as illustrated in FIG. 10, a plurality of capacitors C1 and C2, a plurality of switches SW1 and SW2, a plurality of buffers B1 and B2, and a switch selector 400.

The capacitors C1 and C2 are configured to attenuate a ripple of a feedback signal FB applied to a feedback transmission line 888 to thereby smooth the feedback signal FB. Since the capacitors C1 and C2 illustrated in FIG. 10 are substantially the same as the first and second capacitors C1 and C2 illustrated in FIG. 4, FIG. 4 and related description may be referred to.

The switches SW1 and SW2 are configured to electrically connect the capacitors C1 and C2 and the feedback transmission line 888 or cut the connection therebetween. Since the switches SW1 and SW2 illustrated in FIG. 10 are substantially the same as the first and second of switches SW1 and SW2 illustrated in FIG. 4, FIG. 4 and related description may be referred to.

The buffers B1 and B2 are connected between the switch selector 400 and a gate electrode of each of the switches SW1 and SW2. Since the buffers B1 and B2 illustrated in FIG. 10 are substantially the same as the first and second buffers B1 and B2 illustrated in FIG. 4, FIG. 4 and related description may be referred to.

The switch selector 400 is configured to count a time duration of an externally applied power signal VCC and select one of the switches based on the count result and to turn on the selected switch. Since the switch selector 400 illustrated in FIG. 10 is substantially the same as the switch selector 400 illustrated in FIG. 4, FIG. 4 and related description may be referred to.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings. Various features of the above described and other embodiments can be mixed and matched in any manner, to produce further embodiments consistent with the invention.

1. A signal smoothing device comprising:
a plurality of capacitors connected in parallel between a conductive line and a local reference potential;
a plurality of switches connected in series between the conductive line and each capacitor; and
a switch selector configured to select one of the switches and to turn on the selected switch, based on a signal applied to the conductive line.

2. The signal smoothing device of claim 1, wherein the switch selector selects, instead of a switch currently having turn-on state, another switch and turns on the another selected switch, when the signal applied to the conductive line has a level out of a predetermined range.

3. The signal smoothing device of claim 2, wherein the another switch is one of the other switches except for switches currently having turn-on state or switches having turn-on history.

4. The signal smoothing device of claim 1, wherein the switch selector allows a switch currently having turn-on state to maintain its turn-on state, when the signal applied to the conductive line has a level in a predetermined range.

5. The signal smoothing device of claim 1, wherein the switch selector comprises:
a peak detector configured to detect a peak value of a signal applied to the conductive line;
a comparator configured to compare the peak value provided by the peak detector with a reference value, to produce a comparison signal having different levels based on the comparison result, and to transmit the comparison signal to the peak detector; and
a selector configured to select one of the switches according to the comparison signal applied from the comparator and to output a selection signal to turn on the selected switch.

6. The signal smoothing device of claim 5, wherein:
the comparator outputs a comparison signal having a high logic value; and
the selector applies the selection signal, instead of to a switch currently having turn-on state, to another switch in response to the comparison signal having a high logic value, when the peak value is greater than the reference value.

7. The signal smoothing device of claim 5, wherein the comparator outputs a comparison signal having a low logic value; and
wherein the selector applies the selection signal to a switch currently having turn-on state in response to the comparison signal having a low logic value, when the peak value is less than or equal to the reference value.

8. The signal smoothing device of claim 1, wherein the plurality of capacitors comprises an electrolytic capacitor.

9. A signal smoothing device comprising:
a plurality of capacitors connected in parallel between a conductive line and a local reference potential;
a plurality of switches connected in series between the conductive line and each capacitor; and
a switch selector configured to count a time duration of an externally applied power signal, to select one of the switches based on the count result, and to turn on the selected switch.

10. The signal smoothing device of claim 9, wherein the switch selector selects, instead of a switch currently having turn-on state, another switch, turns on the selected another switch, and counts the time duration again from the beginning, when the time duration of the power signal is out of a predetermined range.

11. The signal smoothing device of claim 10, wherein the another switch is one of the other switches except for switches currently having turn-on state or switches having turn-on history.

12. The signal smoothing device of claim 9, wherein the switch selector allows a switch currently having turn-on state to maintain its turn-on state, when the time duration of the power signal is in a predetermined range.

13. A backlight device comprising:
a light source array connected in series between a driving voltage transmission line and a local reference potential;
a static-current switching element and a sensing resistor;
a light source controller configured to control operation of the static-current switching element and to produce a feedback signal, based on a sensing voltage produced by the sensing resistor;
a backlight driver configured to adjust a voltage level of a light source driving voltage applied to the driving voltage transmission line based on the feedback signal applied from the light source controller;
a feedback transmission line connected between the light source controller and the backlight driver and configured to transmit the feedback signal;
a plurality of capacitors connected in parallel between the feedback transmission line and the local reference potential;
a plurality of switches connected in series between the feedback transmission line and each capacitor; and
a switch selector configured to select one of the switches and to turn on the selected switch, based on the feedback signal applied to the feedback transmission line.

14. The backlight device of claim 13, wherein the switch selector selects, instead of a switch currently having turn-on state, another switch and turns on the selected another switch, when the feedback signal applied to the feedback transmission line has a level out of a predetermined range.

15. The backlight device of claim 14, wherein the another switch is one of the other switches except for switches currently having turn-on state or switches having turn-on history.

16. The backlight device of claim 13, wherein the switch selector allows a switch currently having turn-on state to maintain its turn-on state, when the feedback signal applied to the feedback transmission line has a level in a predetermined range.

17. A backlight device comprising:
a light source array connected in series between a driving voltage transmission line and ground;
a static-current switching element and a sensing resistor;
a light source controller configured to control operation of the static-current switching element and to produce a feedback signal, based on a sensing voltage produced by the sensing resistor;
a backlight driver configured to adjust a voltage level of a light source driving voltage applied to the driving voltage transmission line based on the feedback signal applied from the light source controller;
a feedback transmission line connected between the light source controller and the backlight driver and configured to transmit the feedback signal;
a plurality of capacitors connected in parallel between the feedback transmission line and ground;
a plurality of switches connected in series between the feedback transmission line and each capacitor; and
a switch selector configured to count a time duration of an externally applied power signal, to select one of the switches based on the count result, and to turn on the selected switch.

18. The backlight device of claim 17, wherein the switch selector selects, instead of a switch currently having turn-on state, another switch, turns on the selected another switch, and counts the time duration again from the beginning, when the time duration of the power signal is out of a predetermined range.

19. The backlight device of claim 18, wherein the another switch is one of the other switches except for switches currently having turn-on state or switches having turn-on history.

20. The backlight device of claim 17, wherein the switch selector allows a switch currently having turn-on state to maintain its turn-on state, when the time duration of the power signal is in a predetermined range.
